(19) United States
(12) Patent Application Publication
(10) Pub. No.: US 2023/0020311 A1
(43) Pub. Date: Jan. 19, 2023

(54) METHOD OF MANUFACTURING SEMICONDUCTOR DEVICE, SUBSTRATE PROCESSING APPARATUS AND NON-TRANSITORY COMPUTER-READABLE RECORDING MEDIUM

(71) Applicant: Kokusai Electric Corporation, Tokyo (JP)

(72) Inventor: Shinichiro MORI, Toyama-shi (JP)

(73) Assignee: Kokusai Electric Corporation, Tokyo (JP)

(21) Appl. No.: 17/951,205

(22) Filed: Sep. 23, 2022

Related U.S. Application Data
(63) Continuation of application No. PCT/JP2020/013941, filed on Mar. 27, 2020.

(51) Int. Cl. C23C 16/52

(52) U.S. Cl. CPC C23C 16/52; G06F 3/04817

(57) ABSTRACT

According to one aspect of the technique of the present disclosure, there is provided a method of manufacturing a semiconductor device, including: (A) creating a recipe by setting opening/closing states of a plurality of valves on a gas pattern screen; and (B) processing a substrate by performing the recipe created in (A), wherein (A) includes: (a) selecting a gas pipe on the gas pattern screen when an opening/closing state of any valve among the plurality of valves changes on the gas pattern screen; and (b) confirming opening/closing states of one or more valves connected to the gas pipe selected in (a).

### CROSS-REFERENCE TO RELATED PATENT APPLICATION

This application is a bypass continuation application of PCT International Application No. PCT/JP2020/013941, filed on Mar. 27, 2020, in the WIPO, the entire contents of which are hereby incorporated by reference.

### BACKGROUND

### 1. Field

The present disclosure relates to a method of manufacturing a semiconductor device, a substrate processing apparatus and a non-transitory computer-readable recording medium.

### 2. Related Art

In a substrate processing apparatus, a predetermined process is performed by supplying a gas through a gas supplier (which is a gas supply structure or a gas supply system) to a substrate (hereinafter, also referred to as a “wafer”) in a process chamber of the substrate processing apparatus. A setting operation may be performed by displaying at least the gas supplier on an operation screen. According to the setting operation, for example, data such as a flow rate of the gas flowing through a gas pipe (or a plurality of gas pipes) of each of a plurality of gas suppliers including the gas supplier and opening and closing parameters of a valve (or a plurality of valves) of each of the plurality of gas suppliers may be set.

Until now, a state of a flow of the gas (hereinafter, also referred to as a “gas flow state”) in the gas pipe can be detected or simulated and the opening and closing parameters of the valve can be set by using the operation screen. Further, the flow of the gas (hereinafter, also referred to as a “gas flow”) in the gas pipe can be clearly indicated, for example, by coloring the gas flow.

According to some related arts, there is disclosed a semiconductor manufacturing apparatus capable of detecting and displaying a filling state of the gas pipe with the gas. According to another related arts, there is disclosed a substrate processing apparatus capable of simulating the gas flow when the gas is supplied from a gas source (which is a gas supply source) to a target destination of the gas being supplied. According to still another related art, there is disclosed a substrate processing apparatus capable of performing the setting operation of setting the opening and closing parameters of the valve on the operation screen.

Recently, as a device such as a semiconductor device is miniaturized or involves a deeper structure, a process associated with the device becomes more complicated. Therefore, a wide variety of gases may be used, and depending on a type of the gas, a combination of various valves and various gas pipes may be provided to supply the gas to the process chamber. As a result, a gas pattern diagram showing the valves and the gas pipes may become complicated.

Further, when the gas pattern diagram becomes complicated, it may be difficult to check the gas flow merely by clearly indicating the gas flow in the gas pipes as in the related arts.

### SUMMARY

According to the present disclosure, there is provided a technique capable of confirming a desired state of a flow of a gas while checking which gas pipe is affected when an arbitrary valve is opened on an operation screen.

According to one aspect of the technique of the present disclosure, there is provided a method of manufacturing a semiconductor device, including: (A) creating a recipe by setting opening/closing states of a plurality of valves on a gas pattern screen; and (B) processing a substrate by performing the recipe created in (A), wherein (A) includes: (a) selecting a gas pipe on the gas pattern screen when an opening/closing state of any valve among the plurality of valves changes on the gas pattern screen; and (b) confirming opening/closing states of one or more valves connected to the gas pipe selected in (a).

### BRIEF DESCRIPTION OF THE DRAWINGS

FIG. 1 is a diagram schematically illustrating a substrate processing apparatus 10 preferably used in one or more embodiments of the present disclosure.

FIG. 2 is a diagram schematically illustrating a vertical cross-section of the substrate processing apparatus 10 preferably used in the embodiments of the present disclosure.

FIG. 3 is a diagram schematically illustrating a vertical cross-section of a process furnace 202 of the substrate processing apparatus 10 preferably used in the embodiments of the present disclosure.

FIG. 4 is a block diagram schematically illustrating a configuration of a controller 240 and related components of the substrate processing apparatus 10 preferably used in the embodiments of the present disclosure.

FIG. 5 is a diagram schematically illustrating an example of a gas pattern screen displayed when creating a recipe.

FIG. 6 is a flow chart schematically illustrating a coloring function for gas pipes of the substrate processing apparatus 10 according to the embodiments of the present disclosure.

FIG. 7 is a diagram schematically illustrating an example of a simplified gas pattern diagram used for explaining the flow chart of FIG. 6.

FIGS. 8A through 8C are diagrams schematically illustrating a coloring process for the gas pipes in the simplified gas pattern diagram shown in FIG. 7 with respect to a procedure of supplying a gas from a gas source 247 to the process furnace 202.

FIGS. 9A through 9C are diagrams schematically illustrating the coloring process for the gas pipes in the simplified gas pattern diagram shown in FIG. 7 with respect to the procedure of supplying the gas from the gas source 247 to the process furnace 202.

FIGS. 10A through 10C are diagrams schematically illustrating the coloring process for the gas pipes in the simplified gas pattern diagram shown in FIG. 7 with respect to the procedure of supplying the gas from the gas source 247 to the process furnace 202.

FIGS. 11A through 11C are diagrams schematically illustrating the coloring process for the gas pipes in the simplified gas pattern diagram shown in FIG. 7 with respect to the procedure of supplying the gas from the gas source 247 to the process furnace 202.

FIG. 12 is a diagram schematically illustrating the coloring process for the gas pipes in the simplified gas pattern diagram shown in FIG. 7 with respect to the procedure of supplying the gas from the gas source 247 to the process furnace 202.

FIG. 13 is a diagram schematically illustrating a procedure of setting parameters on an operation screen including the gas pattern screen while performing the coloring process with respect to the gas pipes displayed on the gas pattern screen shown in FIG. 5.

FIG. 14 is a diagram schematically illustrating another procedure of setting the parameters on the operation screen including the gas pattern screen while performing the coloring process with respect to the gas pipes displayed on the gas pattern screen shown in FIG. 5.

FIG. 15 is a diagram schematically illustrating still another procedure of setting the parameters on the operation screen including the gas pattern screen while performing the coloring process with respect to the gas pipes displayed on the gas pattern screen shown in FIG. 5.

FIG. 16 is a flow chart schematically illustrating procedures of creating the recipe when setting the parameters on the gas pattern screen shown in FIG. 5.

### DETAILED DESCRIPTION

### Embodiments of Present Disclosure

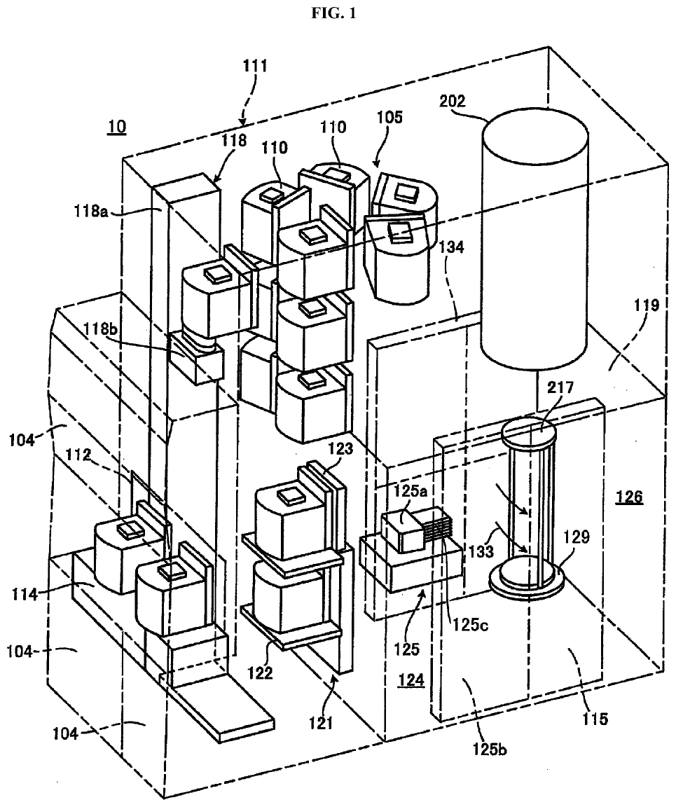

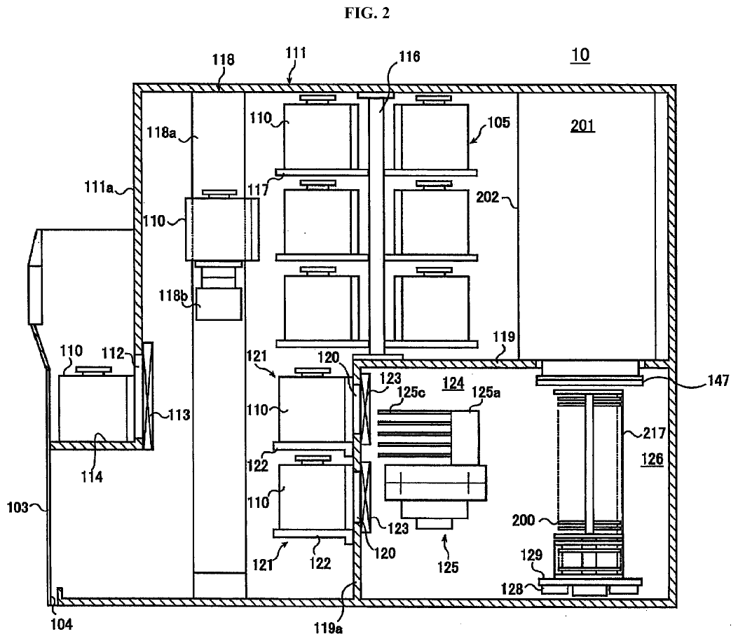

Hereinafter, one or more embodiments (also simply referred to as “embodiments”) according to the technique of the present disclosure will be described with reference to the drawings. First, a substrate processing apparatus 10 to which the technique of the present disclosure is applied will be described with reference to FIGS. 1 and 2.

The substrate processing apparatus 10 includes a housing 111. A front maintenance port 103 serving as an opening provided for maintenance is provided at a lower portion of a front wall 111a of the housing 111. The front maintenance port 103 is configured to be opened or closed by a front maintenance door 104.

A pod loading/unloading port 112 is provided at the front wall 111a of the housing 111 so as to communicate with an inside and an outside of the housing 111. The pod loading/unloading port 112 is configured to be opened or closed by a front shutter 113. A loading port shelf (which is a transfer table for a substrate transfer container) 114 is provided in front of the pod loading/unloading port 112. The loading port shelf 114 is configured such that a pod 110 is aligned while placed on the loading port shelf 114.

The pod 110 is a sealed type substrate transfer container. The pod 110 may be transferred (or loaded) into and placed on the loading port shelf 114 by an in-process transfer apparatus (not shown) and transferred (unloaded) out of the loading port shelf 114 by the in-process transfer apparatus.

A rotatable pod shelf (which is a storage shelf for the substrate transfer container) 105 is provided in the housing 111 to be located over a substantially center portion of the housing 111 in a front-rear direction. The rotatable pod shelf 105 is configured such that a plurality of pods including the pod 110 can be stored (or placed) on the rotatable pod shelf 105. Hereinafter, the plurality of pods including the pod 110 may also be simply referred to as “pods 110”.

The rotatable pod shelf 105 includes a vertical column 116 capable of rotating intermittently and a plurality of shelf plates 117 (which are placing shelves for the substrate transfer container). The plurality of shelf plates 117 are configured to be supported (or fixed) radially by the vertical column 116 at positions of an upper portion, a lower portion and a mid portion of the vertical column 116. Each of the plurality of shelf plates 117 is configured to support the pod 110 when the pod 110 is placed thereon.

A pod opener (which is a structure capable of opening and closing a lid of the substrate transfer container) 121 is provided below the rotatable pod shelf 105. The pod opener 121 is provided with a configuration on which the pod 110 is placed and capable of opening and closing a lid (also referred to as a “cap”) of the pod 110.

A pod transfer structure (which is a container transfer structure) 118 is provided between the loading port shelf 114, the rotatable pod shelf 105 and the pod opener 121. The pod transfer structure 118 is configured such that the pod 110 is capable of being elevated and lowered and being moved forward and backward in a horizontal direction while being supported by the pod transfer structure 118, and such that the pod 110 is capable of being transferred among the loading port shelf 114, the rotatable pod shelf 105 and the pod opener 121.

A sub-housing 119 is provided in the housing 111 at a lower portion thereof and at the substantially center portion of the housing 111 in the front-rear direction to extend toward a rear end of the substrate processing apparatus 10. A pair of wafer loading/unloading ports (which are substrate loading/unloading ports) 120 through which a wafer 200 is transferred (or loaded) into or transferred (or unloaded) out of the sub-housing 119 is provided at a front wall 119a of the sub-housing 119. The pair of wafer loading/unloading ports 120 is arranged vertically in two stages. A pair of pod openers including the pod opener 121 are provided at the pair of wafer loading/unloading ports 120, respectively. For example, an upper pod opener and a lower pod opener may be provided as the pair of pod openers. The upper pod opener and the lower pod opener may be collectively or individually referred to as the “pod opener 121”.

The pod opener 121 may include: a placement table 122 where the pod 110 is placed thereon; and an opening/closing structure 123 capable of opening and closing the lid of the pod 110. The pod opener 121 is configured such that a wafer entrance of the pod 110 is opened or closed by opening or closing the lid of the pod 110 placed on the placement table 122 by the opening/closing structure 123.

The sub-housing 119 defines a transfer chamber 124 fluidically (or airtightly) isolated from a space (hereinafter, also referred to as a “pod transfer space”) in which the pod transfer structure 118 or the rotatable pod shelf 105 is provided. A wafer transfer structure (which is a substrate transfer structure) 125 is provided at a front region of the transfer chamber 124. The wafer transfer structure 125 may include a predetermined number of wafer mounting plates (for example, five wafer mounting plates as shown in FIG. 2) 125c on which a predetermined number of wafers including the wafer 200 are respectively placed. Each of the wafer mounting plates 125c is capable of being moved linearly (or directly) in the horizontal direction, being rotated in the horizontal direction and being elevated or lowered in a vertical direction. The wafer transfer structure 125 is configured to be capable of transferring (loading) the wafer 200 into a boat (which is a substrate retainer or a substrate support) 217 or transferring (unloading) the wafer 200 out of the boat 217.

A standby structure (which is a standby space) 126 where the boat 217 is accommodated and in standby is provided in a rear region of the transfer chamber 124. A vertical type process furnace 202 is provided above the standby structure 126. A process chamber 201 is provided inside the process furnace 202, and a lower end portion of the process chamber 201 is configured as a furnace opening. The furnace opening is opened or closed by a furnace opening shutter (which is a furnace opening opening/closing structure) 147.

A boat elevator (which is an elevator for the substrate retainer) 115 capable of elevating and lowering the boat 217 is provided between a right end portion of the housing 111 and a right end portion of the standby structure 126 of the sub-housing 119. A seal cap 129 serving as a furnace opening lid is horizontally attached to an arm 128 connected to an elevating platform of the boat elevator 115. The seal cap 129 is configured such that the boat 217 can be vertically supported by the seal cap 129, and such that the furnace opening shutter 147 can be airtightly closed by the seal cap 129 while the boat 217 is loaded into the process chamber 201.

The boat 217 is configured such that a plurality of wafers (for example, 25 wafers to 200 wafers) including the wafer 200 are supported on the boat 217 in a horizontal orientation in a multistage manner with their centers aligned with one another. Hereinafter, the plurality of wafers including the wafer 200 may also be simply referred to as wafers 200.

A clean air supply structure 134 is arranged at a position facing the boat elevator 115. The clean air supply structure 134 is constituted by a supply fan and a dustproof filter so as to supply clean air 133 such as an inert gas and a clean atmosphere. A notch alignment device (not shown) serving as a substrate alignment device configured to align a circumferential position of the wafer 200 is provided between the wafer transfer structure 125 and the clean air supply structure 134.

The clean air 133 ejected from the clean air supply structure 134 is circulated in components such as the notch alignment device (not shown), the wafer transfer structure 125 and the boat 217. Thereafter, the clean air 133 is exhausted out of the housing 111 through a duct (not shown), or is ejected again into the transfer chamber 124 by the clean air supply structure 134.

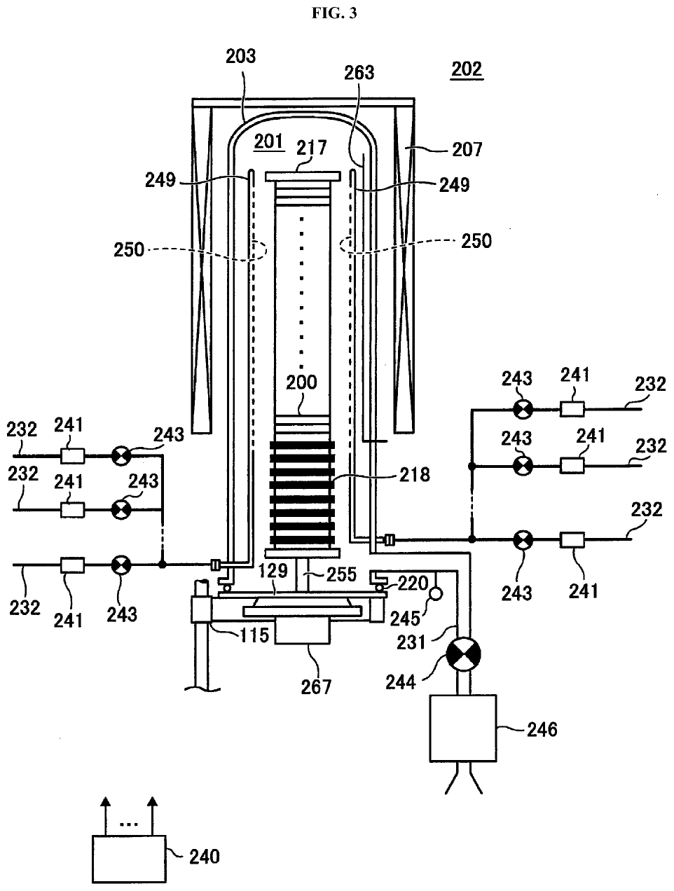

Subsequently, a schematic configuration of the process furnace 202 of the substrate processing apparatus 10 preferably used in the embodiments of the present disclosure will be described with reference to FIG. 3. FIG. 3 is a diagram schematically illustrating a vertical cross-section of the process furnace 202 of the substrate processing apparatus 10.

As shown in FIG. 3, the process furnace 202 is provided with a heater 207 serving as a heating structure (or a temperature regulator). The heater 207 is of a cylindrical shape, and is vertically installed while being supported by a support plate (not shown). The heater 207 also functions as an activator (also referred to as an “exciter”) capable of activating (or exciting) a gas by a heat.

A reaction tube 203 is provided on an inner side of the heater 207 to be aligned in a manner concentric with the heater 207. For example, the reaction tube 203 is made of a heat resistant material such as quartz (SiO₂) and silicon carbide (SiC). The reaction tube 203 is of a cylindrical shape with a closed upper end and an open lower end. The process chamber 201 is provided in a hollow cylindrical portion of the reaction tube 203. The process chamber 201 is configured to accommodate the wafers 200 (each of which serves as a substrate). The wafers 200 are processed in the process chamber 201.

A plurality of nozzles 249 are provided in the process chamber 201 so as to penetrate a lower side wall of the reaction tube 203. A plurality of gas supply pipes 232 are connected to the plurality of nozzles 249, respectively.

A plurality of mass flow controllers (also simply referred to as “MFCs”) 241 serving as flow rate controllers (flow rate control structures) and valves 243 serving as opening/closing valves are sequentially installed at the plurality of gas supply pipes 232, respectively, in this order from upstream sides to downstream sides of the plurality of gas supply pipes 232 in a gas flow direction.

Various gases such as a source gas, the inert gas and a reactive gas are supplied into the process chamber 201 through the plurality of gas supply pipes 232 provided with the plurality of MFCs 241 and the plurality of valve 243, respectively, and the plurality of nozzles 249.

An exhaust pipe 231 through which an inner atmosphere of the process chamber 201 is exhausted is provided at the lower side wall of the reaction tube 203. An exhaust apparatus 246 constituted by a vacuum pump is connected to the exhaust pipe 231 through a pressure sensor 245 and an APC (Automatic Pressure Controller) valve 244. The pressure sensor 245 serves as a pressure detector (pressure detection structure) capable of detecting an inner pressure of the process chamber 201, and the APC valve 244 serves as a pressure regulator (pressure adjusting structure). With the exhaust apparatus 246 in operation, the APC valve 244 may be opened or closed to vacuum-exhaust the process chamber 201 or stop vacuum-exhausting the process chamber 201. With the exhaust apparatus 246 in operation, the inner pressure of the process chamber 201 may be adjusted by adjusting an opening degree of the APC valve 244 based on pressure information detected by the pressure sensor 245. An exhauster (which is an exhaust structure or an exhaust system) is constituted mainly by the exhaust pipe 231, the pressure sensor 245 and the APC valve 244. The exhauster may further include the exhaust apparatus 246.

Further, the gas supply pipes 232 and the exhaust pipe 231 may also be collectively or individually referred to as a “gas pipe”.

Further, the seal cap 129 serving as a furnace opening lid capable of airtightly sealing (or closing) a lower end opening of the reaction tube 203 is provided under the reaction tube 203. For example, the seal cap 129 is made of a metal material such as SUS, and is of a disk shape. An O-ring 220 serving as a seal is provided on an upper surface of the seal cap 129 so as to be in contact with the lower end of the reaction tube 203. A rotator 267 configured to rotate the boat 217 described later is provided under the seal cap 129. For example, a rotating shaft 255 of the rotator 267 is connected to the boat 217 through the seal cap 129. As the rotator 267 rotates the boat 217, the wafers 200 accommodated in the boat 217 are rotated. The seal cap 129 is configured to be elevated or lowered in the vertical direction by the boat elevator 115 serving as an elevator provided outside the reaction tube 203. The boat elevator 115 serves as a transfer structure (which is a transfer apparatus) capable of loading the boat 217 and the wafers 200 accommodated in the boat 217 into the process chamber 201 or unloading the boat 217 and the wafers 200 accommodated in the boat 217 out of the process chamber 201 by elevating or lowering the seal cap 129.

The boat 217 serving as the substrate support is configured such that the wafers 200 (for example, 25 wafers to 200 wafers) are accommodated (or supported) in the vertical direction in the boat 217 while the wafers 200 are horizontally oriented with their centers aligned with one another with a predetermined interval therebetween in a multistage manner. For example, the boat 217 is made of a heat resistant material such as quartz and SiC. For example, a plurality of heat insulation plates 218 made of a heat resistant material such as quartz and SiC are provided below the boat 217 to be supported in a horizontal orientation in a multistage manner.

A temperature sensor 263 serving as a temperature detector is installed in the reaction tube 203. A state of electric conduction to the heater 207 is adjusted based on temperature information detected by the temperature sensor 263 such that a desired temperature distribution of an inner temperature of the process chamber 201 can be obtained. The temperature sensor 263 is provided along an inner wall of the reaction tube 203.

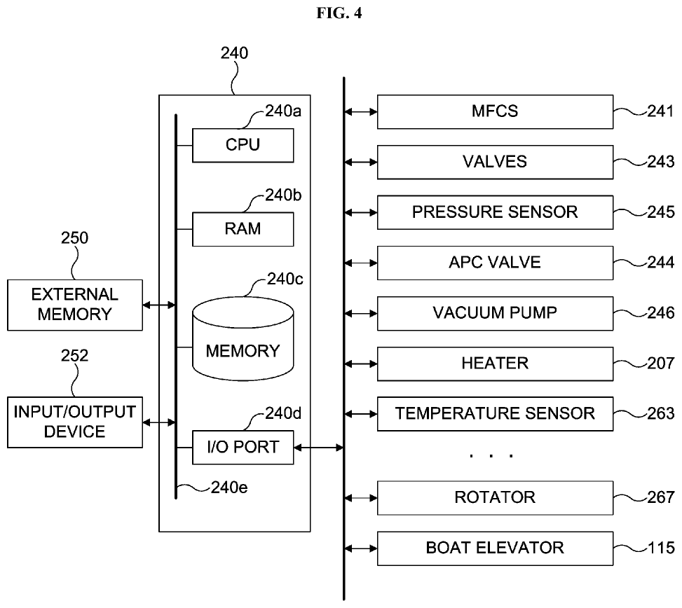

As shown in FIG. 4, for example, a controller 240 serving as a control structure (control device) is constituted by a computer including a CPU (Central Processing Unit) 240a, a RAM (Random Access Memory) 240b, a memory 240c and an I/O port (input/output port) 240d. The RAM 240b, the memory 240c and the I/O port 240d may exchange data with the CPU 240a through an internal bus 240e. For example, an input/output device 252 constituted by a component such as a touch panel is connected to the controller 240.

For example, the memory 240c is constituted by a component such as a flash memory and a hard disk drive (HDD). For example, a control program configured to control operations of the substrate processing apparatus 10 and a recipe such as a process recipe containing information on sequences (or procedures) (hereinafter, also referred to as “steps”) and conditions of a predetermined process may be readably stored in the memory 240c. The process recipe constituted mainly by the steps is obtained by combining the steps (which is the sequences or the procedures) of the predetermined process such that the controller 240 can execute the steps to acquire a predetermined result, and functions as a program. Hereinafter, the control program and the recipe including the process recipe may be collectively or individually referred to as a “program”. In addition, hereinafter, the process recipe may also be simply referred to as the “recipe”. Thus, in the present specification, the term “program” may refer to the recipe alone, may refer to the control program alone, or may refer to both of the recipe and the control program. The RAM 240b functions as a memory area (work area) where the program or data read by the CPU 240a is temporarily stored.

The I/O port 240d is connected to the above-described components such as the MFCs 241, the valves 243, the pressure sensor 245, the APC valve 244, the exhaust apparatus 246, the temperature sensor 263, the heater 207, the rotator 267 and the boat elevator 115.

The CPU 240a is configured to read the control program from the memory 240c and execute the read control program. In addition, the CPU 240a is configured to read the recipe from the memory 240c in accordance with an operation command inputted from the input/output device 252. According to the contents of the read recipe, the CPU 240a may be configured to be capable of controlling various operations such as flow rate adjusting operations for various gases by the MFCs 241, opening and closing operations of the valves 243, an opening and closing operation of the APC valve 244, a pressure adjusting operation by the APC valve 244 based on the pressure sensor 245, a start and stop of the exhaust apparatus 246, a temperature adjusting operation by the heater 207 based on the temperature sensor 263, an operation of adjusting a rotation and a rotation speed of the boat 217 by the rotator 267 and an elevating and lowering operation of the boat 217 by the boat elevator 115.

The controller 240 may be embodied by installing the above-described program stored in an external memory 250 into the computer. For example, the external memory 250 may include a magnetic disk such as a hard disk drive (HDD), an optical disk such as a CD, a magneto-optical disk such as an MO and a semiconductor memory such as a USB memory. The memory 240c or the external memory 250 may be embodied by a non-transitory computer readable recording medium. Hereafter, the memory 240c and the external memory 250 may be collectively or individually referred to as a “recording medium”. Thus, in the present specification, the term “recording medium” may refer to the memory 240c alone, may refer to the external memory 250 alone, or may refer to both of the memory 240c and the external memory 250. In addition, instead of the external memory 250, a communication structure such as the Internet and a dedicated line may be used for providing the program to the computer.

In the substrate processing apparatus 10 according to the present embodiments, when the recipe is created by setting a plurality of parameters, by displaying a gas pattern screen indicating a gas pattern diagram including the valves and the gas pipes and by simulating, on the gas pattern screen, which valve (or valves) should be opened to supply the gas from a gas source (which is a gas supply source) to a target destination of the gas being supplied (hereinafter, also referred to as a “target gas supply destination”), it is possible to create the recipe while setting the parameters such as opening and closing parameters of the valve (or valves).

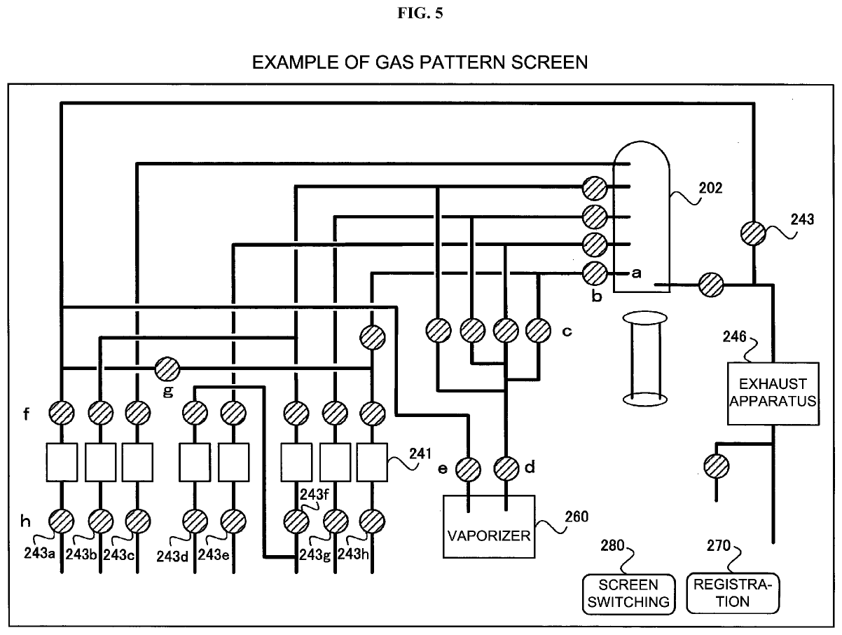

On the gas pattern screen shown in FIG. 5, a state in which the MFCs 241, the valves 243 and various components such as a vaporizer 260, the process furnace 202 and the exhaust apparatus 246 are connected by the gas pipes provided therebetween similar to a network is displayed. In particular, valves 243a, 243b, 243c, 243d, 243e, 243f, 243g and 243h are illustrated as valves closest to the gas source (or gas sources) (not shown).

It is possible to monitor an opening/closing state indicating whether a specified valve is in an open state or in a closed state by seeing the gas pattern screen. Specifically, by switching a displayed color of the specified valve according to whether the specified valve is in the open state or in the closed state, it is possible to know whether the specified valve is in the open state or in the closed state.

Further, in addition to the monitoring function of monitoring the opening/closing state of the valve, an operation function of switching the opening/closing state of any chosen valve by a user is provided on the gas pattern screen. By using the valve operation function, the user can switch the opening/closing state of the valve between the open state and the closed state by pressing an image of the valve displayed on the gas pattern diagram. In addition, it is possible to simultaneously press images of a plurality of valves so as to switch opening/closing states of the plurality of valves.

Furthermore, a simulation function may also be provided on the gas pattern screen. The simulation function is to show the user, before actually operating the valve, a simulation results by changing displayed colors of the gas pipes to indicate which gas pipes the gas will flow through if a certain valve is operated to change its opening/closing state.

Further, in the substrate processing apparatus 10 according to the present embodiments, by enlarging an operation screen, it is possible to display the gas pattern diagram including not only the valves 243 but also the components such as the process furnace 202, the MFCs 241 serving as the flow rate controllers, the vaporizer 260, the APC valve 244 serving as the pressure regulator and the transfer structure on the same screen such as the operation screen together with the parameters such as a temperature, a pressure and parameters for the transfer structure (which are not shown). Therefore, by setting the valves 243, the components described above or the parameters displayed in the gas pattern diagram without switching the operation screen, it is possible to set the steps displayed on the operation screen. By using a screen switching button 280 serving as a screen switching interface, it is possible to create the recipe while switching the steps. Further, by using the gas pattern screen on which various components described above are displayed, it is possible to set the parameters by using the gas flow simulation function. Thereby, even a novice user can easily create the recipe.

The controller 240 is configured to be capable of, when creating the recipe on the operation screen, accepting (or receiving) a setting of the opening/closing state of the valve by using the gas pattern screen shown in FIG. 5 while displaying at least the parameters on the operation screen. In addition, the controller 240 is configured be capable of accepting (or receiving) settings of at least one parameter selected from the group consisting of the temperature, the pressure and the parameters for the transfer structure (which are not shown). However, the temperature, the pressure and the parameters for the transfer structure are merely examples of the parameters, and the parameters displayed on the operation screen can be appropriately set in accordance with the recipe.

Further, the gas pattern screen is configured to at least display one or more valves located within a range from a supplier (which is a supply system) capable of supplying a source material such as the gas into a reaction chamber (that is, the process chamber 201) to an exhauster (which is an exhaust system) capable of exhausting (or decompressing) an inner atmosphere of the reaction chamber such that an inner pressure of the reaction chamber reaches and is maintained at a vacuum level (vacuum atmosphere). Thereby, it is possible to set various parameters for the components such as the MFCs 241 serving as the flow rate controllers, the vaporizer 260, the exhaust apparatus 246 and the APC valve 244 serving as the pressure regulator, which are displayed on the gas pattern screen by using icons.

Further, a registration button 270 serving as a registration interface configured to register the parameters which are set by using the gas pattern screen is provided on the operation screen. The registration button 270 is configured to accept the setting contents of the parameters when it is pressed.

For example, the registration button 270 is configured to be capable of being pressed when an entirety of the valves between the gas source and the target gas supply destination on the gas pattern screen are in the open state and when the gas from the gas source reaches the target gas supply destination.

That is, the registration button 270 is configured to be incapable of being pressed when a valve between the gas source and the target gas supply destination on the gas pattern screen is not in the open state.

Further on the operation screen is provided the screen switching button 280 capable of being pressed after the setting contents of the parameters is accepted (or received) by the registration button 270 and capable of switching a screen such as the operation screen from that for a step to that for another step.

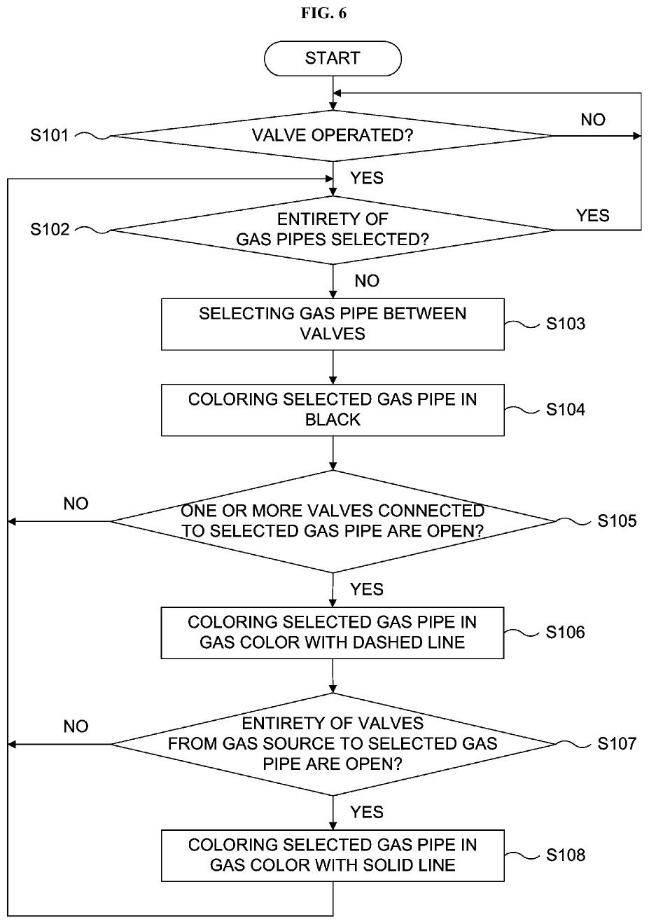

Subsequently, a coloring function for the gas pipes (which is the gas flow simulation display function) of the substrate processing apparatus 10 according to the present embodiments will be described with reference to a flow chart shown in FIG. 6. According to the present embodiments, the function shown in FIG. 6 is enabled when, for example, the gas pattern screen shown in FIG. 5 is displayed on the operation screen. However, for example, when a setting button (not shown) or one of the valves 243 on the gas pattern screen is pressed, the function shown in FIG. 6 may be enabled out of its disabled state, and steps of the flow chart shown in FIG. 6 may be started.

Referring to FIG. 6, first, in a step S101, the controller 240 determines whether or not a valve among the valves 243 on the gas pattern screen is operated. A standby state is maintained until the valve among the valves 243 is operated. The present embodiments will be described based on the valves 243, in particular. However, a coloring of the gas pipe may be adjusted in accordance with a set value of an MFC such as the MFCs 241. For example, a thickness of a line may be changed in accordance with the set value of the MFC.

Then, when it is determined, in the step S101, that the valve among the valves 243 on the gas pattern screen is operated, the controller 240 determines in a step S102 whether or not an entirety of the gas pipes displayed on the gas pattern diagram are selected.

When it is determined, in the step S102, that the entirety of the gas pipes are selected, the step S101 is performed again by the controller 240, and the standby state is maintained until the valve among the valves 243 is operated.

Further, when it is determined, in the step S102, that the entirety of the gas pipes are not selected, in a step S103, the controller 240 selects a gas pipe which is not yet selected among the gas pipes between the valves displayed on the gas pattern screen. Hereinafter, the gas pipe selected in the step S103 may also be referred to as a “selected gas pipe”.

Then, in a step S104, the controller 240 colors the selected gas pipe in black.

Subsequently, in a step S105, the controller 240 determines whether or not one or more valves connected to the selected gas pipe are in the open state.

Then, when it is determined, in the S105, that one or more valves connected to the selected gas pipe are in the open state, in a step S106, the controller 240 colors the selected gas pipe in a gas color with a dashed line. In the present specification, the term “gas color” refers to a color indicating that the gas is being supplied. For example, an appropriate color such as yellow, blue and green may be used as the gas color.

Subsequently, in a step S107, the controller 240 determines whether or not the entirety of the valves within a range from the gas source to the selected gas pipe are in the open state.

Then, when it is determined, in the step S107, that the entirety of the valves within a range from the gas source to the selected gas pipe are in the open state, in a step S108, the controller 240 colors the selected gas pipe in the gas color with a solid line.

Further, when it is determined, in the step S105, that one or more valves connected to the selected gas pipe are not in the open state, or it is determined, in the step S107, that the entirety of the valves within the range from the gas source to the selected gas pipe are not in the open state, the step S102 is performed again by the controller 240.

When the valve among the valves 243 is operated and its opening/closing state is switched by performing the process described above, the controller 240 sequentially selects the entirety of the gas pipes displayed on the gas pattern screen one by one, and repeatedly performs the steps S102 through S108.

Although not included in the flow chart shown in FIG. 6, the opening/closing state of the valves such as the valves 243 may be saved (or stored) by pressing the registration button 270 shown in FIG. 5 after completing the setting of the opening/closing state of each of the valves by repeatedly performing the steps S102 through S108. Alternatively, instead of the registration button 270, a save button (not shown) or the like may be used to save the setting of the opening/closing state of each of the valves.

Subsequently, a coloring process for the gas pipes described in the flow chart of FIG. 6 will be specifically described by way of an example in which a simplified gas pattern diagram is used.

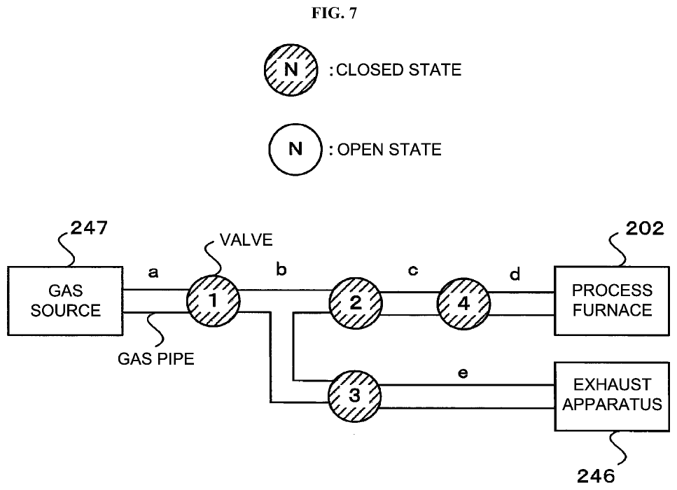

An example of the simplified gas pattern diagram used for describing the coloring process for the gas pipes is illustrated in FIG. 7. According to the present embodiments, the simplified gas pattern diagram (which is the gas pattern diagram with a simple configuration) is used in order to describe procedures of the coloring process for the gas pipes. Specifically, in the simplified gas pattern diagram shown in FIG. 7, the gas source 247, the process furnace 202 and the exhaust apparatus 246 are connected by five gas pipes (that is, a gas pipe “a”, a gas pipe “b”, a gas pipe “c”, a gas pipe “d” and a gas pipe “e”) and four valves (that is, a valve “1”, a valve “2”, a valve “3” and a valve “4”).

According to the present embodiments, when a valve among the valves “a” through “e” is indicated by a diagonal line, it indicates that the valve is in the closed state, and when the valve among the valves “a” through “e” is displayed in white, it indicates that the valve is in the open state.

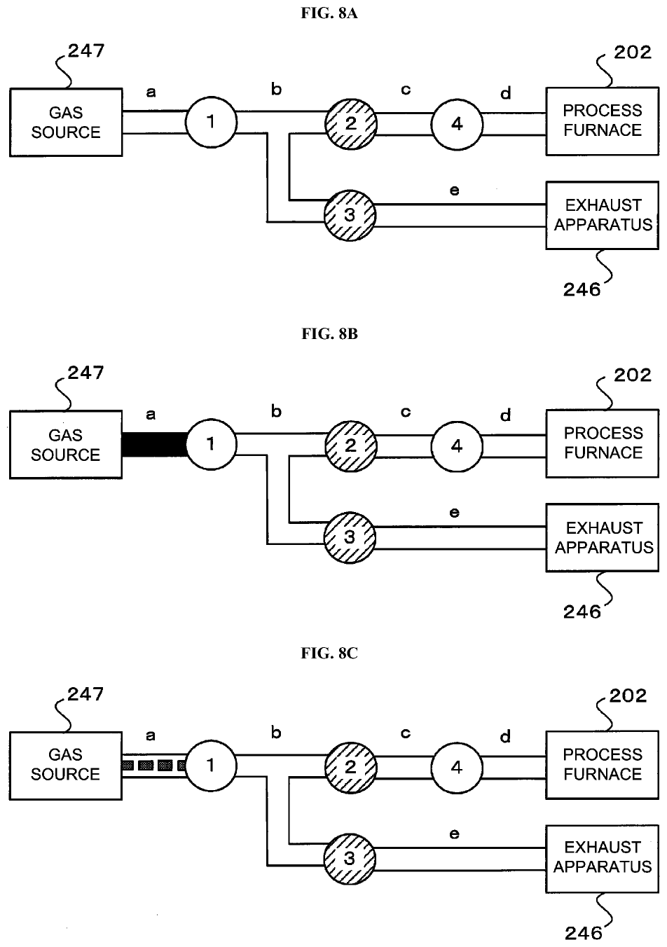

Subsequently, a case in which the user creates the recipe for procedures of supplying the gas from the gas source 247 to the process furnace 202 according to the simplified gas pattern diagram shown in FIG. 7 will be described with reference to FIGS. 8A through 12.

First, as shown in FIG. 8A, the case in which the user creates the recipe will be described by way of an example in which the user has switched the valve 1 closest to the gas source 247 and the valve 4 closest to the process furnace 202 to the open state.

Since the opening/closing states of the valves 1 and 4 are switched as described above, the controller 240 sequentially selects the five gas pipes, that is, the gas pipes “a” through “e” and performs the coloring process as described above.

First, in the step S102, the controller 240 determines whether or not the entirety of the gas pipes are selected. However, since no gas pipe is selected yet, the step S103 is performed by the controller 240.

In the step S103, the controller 240 selects a gas pipe among the gas pipes “a” through “e”. For example, it is assumed that the controller 240 selects the gas pipe “a”.

Therefore, the controller 240 colors the selected gas pipe (that is, the gas pipe “a”) in black, as shown in FIG. 8B.

Subsequently, in the step S105, the controller 240 determines whether or not one or more valves connected to the selected gas pipe (that is, the gas pipe “a”) are in the open state. Since the valve 1 connected to the gas pipe “a” is in the open state, the controller 240 colors the gas pipe “a” in the gas color with the dashed line, as shown in FIG. 8C.

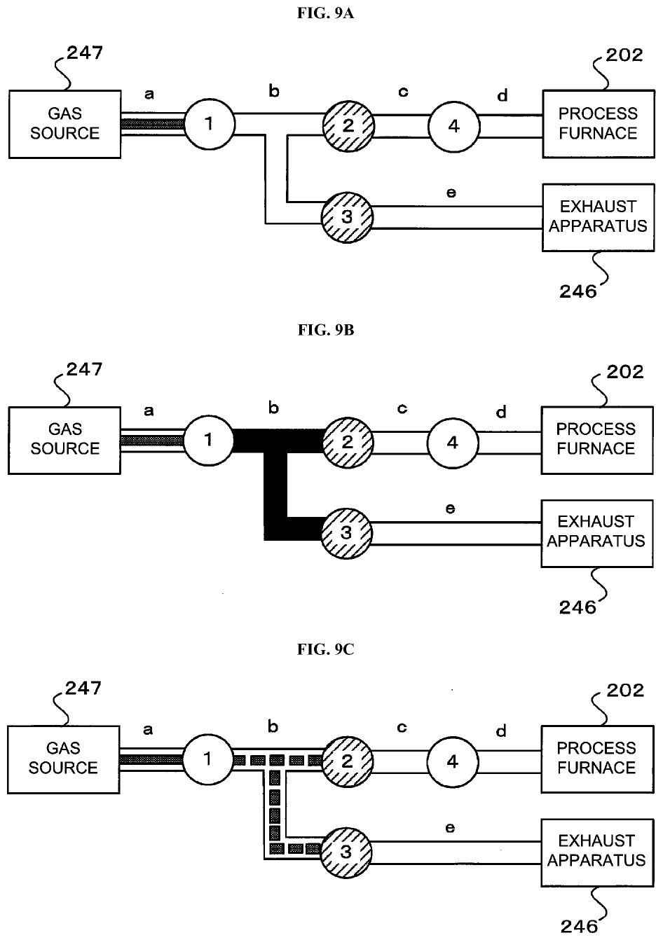

Further, in the step S107, the controller 240 determines whether or not the entirety of the valves within the range from the gas source 247 to the selected gas pipe (that is, the gas pipe “a”) are in the open state. Since no valve is present within the range from the gas source 247 to the gas pipe “a”, the controller 240 colors the gas pipe “a” in the gas color with the solid line, as shown in FIG. 9A.

Subsequently, the step S102 is performed again by the controller 240, and it is determined whether or not the entirety of the gas pipes are selected. However, since the gas pipe “a” alone is selected and the gas pipes “b” through “e” are not yet selected, the step S103 is performed again by the controller 240.

For example, it is assumed that the controller 240 selects the gas pipe “b” in the step S103.

Therefore, the controller 240 colors the selected gas pipe (that is, the gas pipe “b”) in black, as shown in FIG. 9B.

Subsequently, in the step S105, the controller 240 determines whether or not one or more valves connected to the selected gas pipe (that is, the gas pipe “b”) are in the open state. Since the valve 1 connected to the gas pipe “b” is in the open state, the controller 240 colors the gas pipe “b” in the gas color with the dashed line, as shown in FIG. 9C.

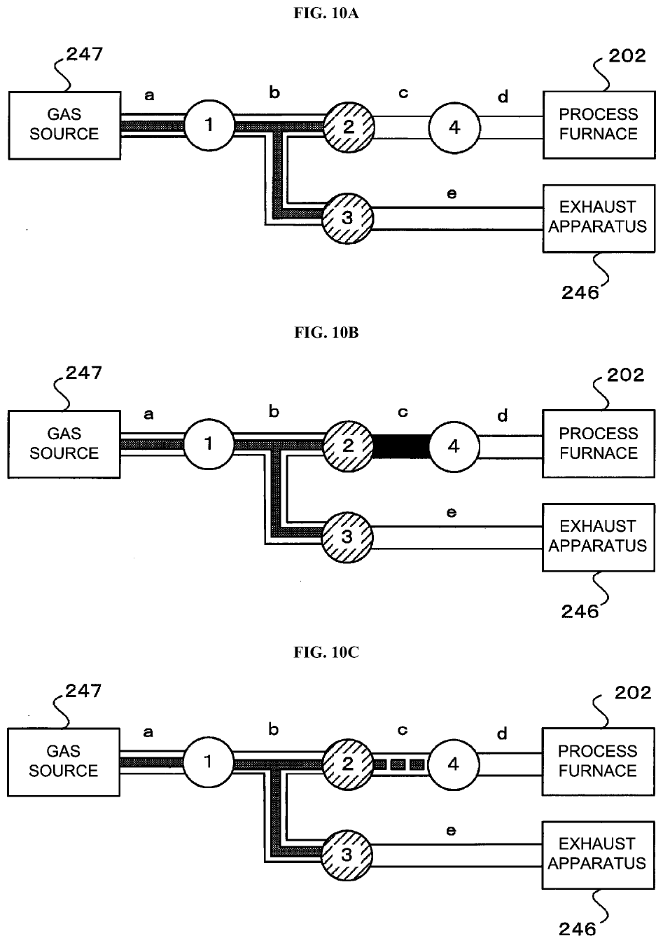

Further, in the step S107, the controller 240 determines whether or not the entirety of the valves within the range from the gas source 247 to the selected gas pipe (that is, the gas pipe “b”) are in the open state. Since the valve 1 located within the range from the gas source 247 to the selected gas pipe (that is, the gas pipe “b”) is in the open state, the controller 240 colors the gas pipe “b” in the gas color with the solid line, as shown in FIG. 10A.

Subsequently, the step S102 is performed again by the controller 240, and it is determined whether or not the entirety of the gas pipes are selected. However, since the gas pipe “a” and the gas pipe “b” are selected and the gas pipes “c” through “e” are not yet selected, the step S103 is performed again by the controller 240.

For example, it is assumed that the controller 240 selects the gas pipe “c” in the step S103.

Therefore, the controller 240 colors the selected gas pipe (that is, the gas pipe “c”) in black, as shown in FIG. 10B.

Subsequently, in the step S105, the controller 240 determines whether or not one or more valves connected to the selected gas pipe (that is, the gas pipe “c”) are in the open state. Since the valve 4 connected to the gas pipe “c” is in the open state, the controller 240 colors the gas pipe “c” in the gas color with the dashed line, as shown in FIG. 10C.

Further, in the step S107, the controller 240 determines whether or not the entirety of the valves within the range from the gas source 247 to the selected gas pipe (that is, the gas pipe “c”) are in the open state. Since, among the valves within the range from the gas source 247 to the selected gas pipe (that is, the gas pipe “c”), the valve 1 is in the open state but the valve 2 is in the closed state, the controller 240 maintains the gas pipe “c” in the gas color shown with the dashed line.

Subsequently, the step S102 is performed again by the controller 240, and it is determined whether or not the entirety of the gas pipes are selected. However, since the gas pipes “a” through “c” are selected and the gas pipes “d” and “e” are not yet selected, the step S103 is performed again by the controller 240.

For example, it is assumed that the controller 240 selects the gas pipe “d” in the step S103.

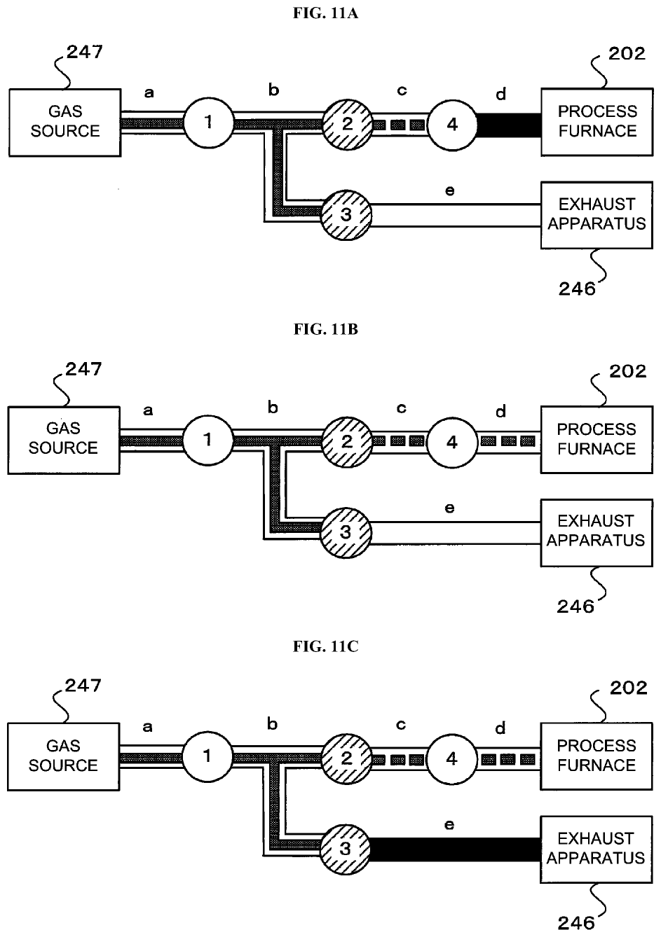

Therefore, the controller 240 colors the selected gas pipe (that is, the gas pipe “d”) in black, as shown in FIG. 11A.

Subsequently, in the step S105, the controller 240 determines whether or not one or more valves connected to the selected gas pipe (that is, the gas pipe “d”) are in the open state. Since the valve 4 connected to the gas pipe “d” is in the open state, the controller 240 colors the gas pipe “d” in the gas color with the dashed line, as shown in FIG. 11B.

Further, in the step S107, the controller 240 determines whether or not the entirety of the valves within the range from the gas source 247 to the selected gas pipe (that is, the gas pipe “d”) are in the open state. Since, among the valves within the range from the gas source 247 to the selected gas pipe (that is, the gas pipe “d”), the valves 1 and 4 are in the open state but the valve 2 is in the closed state, the controller 240 maintains the gas pipe “d” in the gas color shown with the dashed line.

Subsequently, the step S102 is performed again by the controller 240, and it is determined whether or not the entirety of the gas pipes are selected. However, since the gas pipes “a” through “d” are selected and the gas pipe “e” is not yet selected, the step S103 is performed again by the controller 240.

For example, it is assumed that the controller 240 selects the gas pipe “e” in the step S103.

Therefore, the controller 240 colors the selected gas pipe (that is, the gas pipe “e”) in black, as shown in FIG. 11C.

Subsequently, in the step S105, the controller 240 determines whether or not one or more valves connected to the selected gas pipe (that is, the gas pipe “e”) are in the open state. Since the valve 3 connected to the gas pipe “e” is in the closed state, the controller 240 maintains the gas pipe “e” black.

Subsequently, the step S102 is performed again by the controller 240, and it is determined whether or not the entirety of the gas pipes are selected. Since the entirety of the gas pipes, that is, the gas pipes “a” through “e” are selected, the step S101 is performed again by the controller 240, and the coloring process of the gas pipes is terminated.

By switching the valves 1 and 4 to the open state and by performing the steps as describe above, the simplified gas pattern diagram is finally colored as shown in FIG. 11C.

The user who sees the simplified gas pattern diagram colored as shown in FIG. 11C can understand that the valve 2 provided between the gas pipe “b” colored in the gas color with the solid line and the gas pipe “c” colored in the gas color with the dashed line should be opened in order to supply the gas from gas source 247 to the process furnace 202.

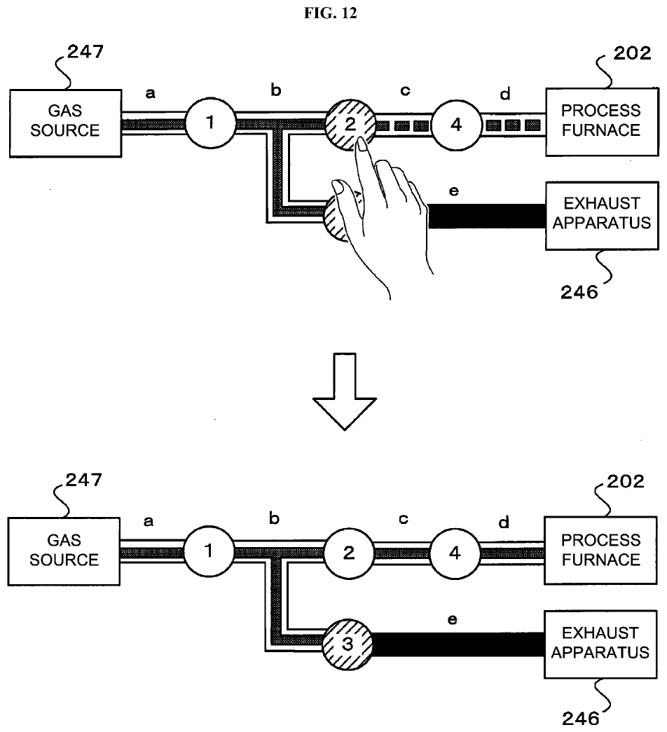

When the user switches the valve 2 from the closed state to the open state, the gas pipes “c” and “d” are colored in the gas color with the solid line as shown in FIG. 12 by repeatedly performing the steps similar to those described above.

As described above, the controller 240 is configured to be capable of performing at least the following steps on the gas pattern screen shown in FIG. 5, that is, a step (a) corresponding to the step S102 and the step S103 described above, a step (b) corresponding to the step S105 described above and a step (c) corresponding to the step S107 described above.

That is, the controller 240 is configured to be capable of performing:

(a) sequentially selecting the entirety of the gas pipes on the gas pattern screen when the opening/closing state of the valve among the valves on the gas pattern screen changes;

(b) checking the opening/closing state of the valve (or valves) connected to the selected gas pipe; and

(c) checking whether the entirety of the valves between the gas source and the selected gas pipe are in the open state.

Then, in the step (b), when any one of the valves connected to the selected gas pipe is in the open state, the controller 240 is configured to perform the step S106 of coloring the selected gas pipe in an appropriate color (for example, yellow) with the dashed line.

Further, in the step (b), when the entirety of the valves connected to the selected gas pipe are in the closed state, the controller 240 is configured to terminate a process for the selected gas pipe and performs a process for a subsequent gas pipe.

Further, in the step (c), when the entirety of the valves within a range from the gas source to the selected gas pipe are in the open state, the controller 240 is configured to perform the step S108 of switching the coloring state of the selected gas pipe from the dashed line in the appropriate color (for example, yellow) to the solid line in the appropriate color. Further, in the step (a), it is also possible that a selection of the gas pipe is not accompanied by a display change on the gas pattern screen. That is, it is sufficient that the gas pipe is logically selected inside the controller 240.

As described above, according to the present embodiments, by displaying the state of the gas flow on the gas pattern screen by the controller 240, it is possible to easily see which gas pipe is affected when the user opens an arbitrary valve by using the operation screen.

Conventionally, when the opening/closing state of an arbitrary valve displayed on the gas pattern screen is switched from the closed state to the open state, a graphic display of the gas pipe connected to that valve could not be changed in a case where the gas has not reached that valve, that is, in a case where no gas flow has occurred. As a result, it was difficult to know which gas pipe may be affected by that valve switched to the open state. However, according to the present embodiments, the function of coloring is available even when there is no gas flow. Therefore, it is possible to trace an effect of a valve switched to the open state on a gas pipe even when the valve is not yet reached by the gas by tracing the gas pipe by using the valve as a starting point.

According to the present embodiments, it is possible to accurately set the opening/closing state of the valve regardless of the skill of the user. In other words, conventionally, a veteran user who is familiar with a structure of the gas pattern diagram could instantaneously determine the structure of the gas pattern diagram (which is complicated) and accurately set the opening/closing state of the valve. However, according to the present embodiments, even when a novice user operates an arbitrary valve on the gas pattern diagram, it is possible to display the state of the gas flow on the gas pattern diagram. As a result, it is possible to work while grasping the state of the gas flow on the screen when the valve is opened or closed. Further, it is possible to suppress a problem such as a delay in a work time in setting the opening/closing state of the valve.

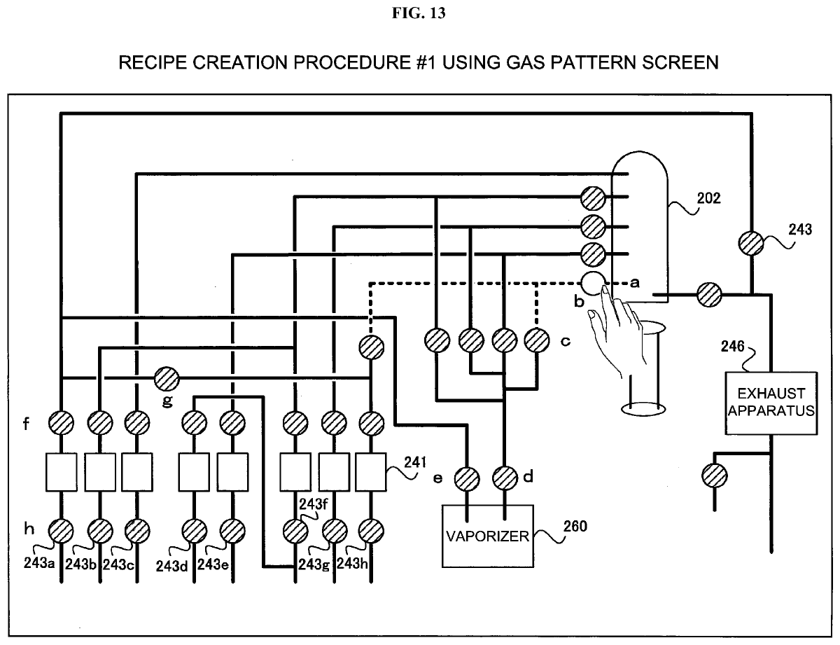

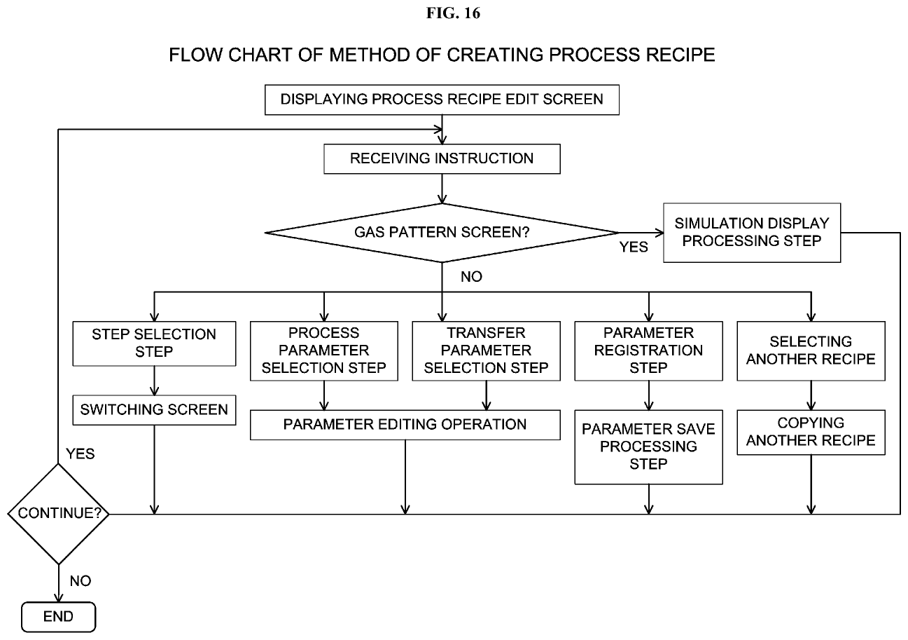

Subsequently, by using the coloring process for the gas pipes as described above, a case in which the setting of the opening/closing state of the valve displayed on the gas pattern screen shown in FIG. 5 is applied to create the recipe will be described with reference to a flow chart shown in FIG. 16. In particular, the setting of the opening/closing state of the valve on the gas pattern screen will be described with reference to FIGS. 13 through 15.

First, a recipe edit screen for creating the recipe is displayed on the operation screen. When displaying the recipe edit screen, the function of the flow chart shown in FIG. 6 is enabled. Then, when the controller 240 accepts (or receives) an operation (or an instruction) on the recipe edit screen, the controller 240 confirms whether or not the operation (or an instruction) is generated by using the gas pattern screen.

When it is confirmed that the operation on the recipe edit screen is generated by using the gas pattern screen, a simulation display processing step is performed. That is, the step S101 of the flow chart shown in FIG. 6 is performed by the controller 240.

Hereinafter, a case in which the valve on the gas pattern screen is operated and the simulation display processing step shown in FIG. 16 is performed by the controller 240 will be described. Specifically, based on the gas pattern diagram shown in the gas pattern screen of FIG. 5, it will be described as to a case in which the opening/closing states of the valves are set such that the gas supplied from the valve 243a at a location “h” closest to the gas source is supplied to a supply location “a” of the process furnace 202 through the vaporizer 260. In the following, descriptions of the coloring of the gas pipes in FIGS. 13 through 15 will be omitted.

According to the present embodiments, it is preferable that some valves are switched to the open state such that the gas passes through the vaporizer 260 by tracing the gas pipes from a destination to which the gas is to be supplied. Specifically, as shown in FIG. 13, it is preferable that the valve “b” closest to the supply location “a” in the process furnace 202 is switched to the open state.

Referring to FIG. 13, it is possible to see that the gas pipes connected to both sides of the valve “b” in the open state are colored in the gas color with the dashed line. Then, in FIG. 16, the simulation display processing step is terminated, and it is determined whether to terminate or continue an editing operation by receiving a subsequent operation (or a subsequent instruction).

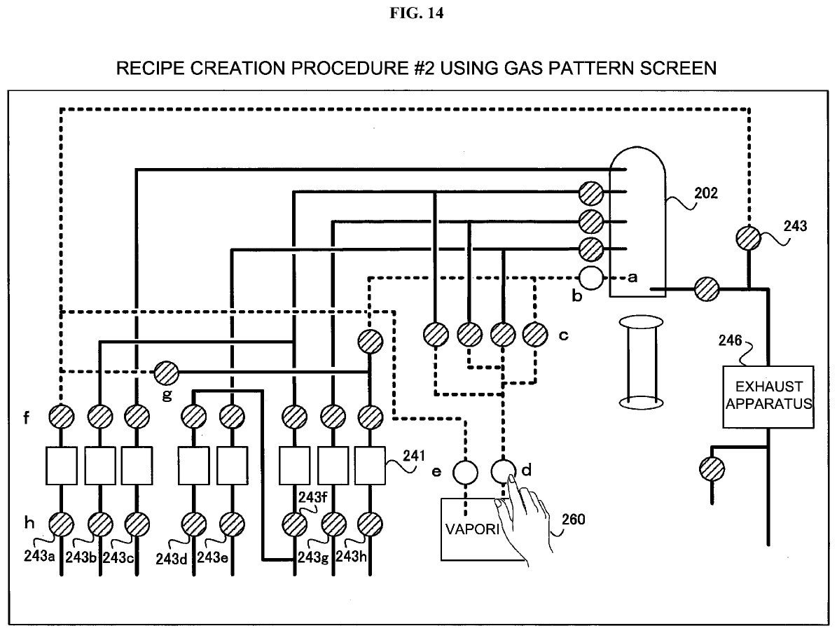

Subsequently, as shown in FIG. 14, it is preferable that the valves “e” and “d” connected to an input side and an output side of the vaporizer 260 through which the gas flows are switched to the open state.

Referring to FIG. 14, it is possible to see that the gas pipes connected to the valves “e” and “d” in the open state are colored in the gas color with the dashed line. Then, similarly, in FIG. 16, the simulation display processing step is terminated, and it is determined whether to terminate or continue the editing operation by receiving a subsequent operation (or a subsequent instruction).

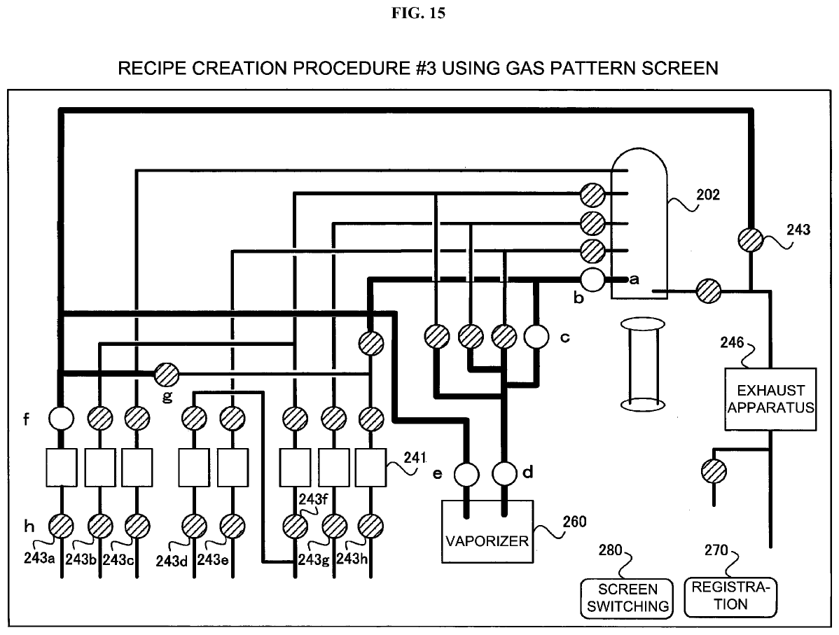

The user who sees the gas pattern diagram as shown in FIG. 14 can easily understand that the valves to be switched to the open state subsequently are the valves “c” and “f”. The gas pattern screen on which the gas pattern diagram after the user has switched the valves “c” and “f” to the open state is displayed in FIG. 15. That is, a result of accepting an operation (or an instruction) on the gas pattern screen and performing the simulation display processing step of FIG. 16 is displayed in FIG. 15.

Strictly speaking, the valve 243 on an exhaust side of the process furnace 202 is also to be switched to the open state. However, the description thereof will be omitted.

In the gas pattern screen shown in FIG. 15, it is possible to see that the gas supplied through the valve 243a at the location “h” is supplied to the vaporizer 260 via the valve “f” and the valve “e”, and that the gas pipes through which the gas from the vaporizer 260 is supplied to the supply location “a” of the processing furnace 202 via the valve “d”, the valve “c” and the valve “b” are colored in the gas color with the solid line. That is, in FIG. 16, the simulation display processing step is terminated, and it enters a standby state to determine whether to terminate or continue the editing operation by receiving a subsequent operation (or a subsequent instruction).

Then, when the gas from the gas source 247 reaches the process furnace 202 which is the supply destination, the registration button 270 may be displayed as shown in FIG. 15 such that the registration button 270 can be pressed. By pressing the registration button 270, various parameters are set. Thus, the setting of the opening/closing state of each of the valves cannot be registered in a state in which the gas has not yet flown thereto. Therefore, it is possible to reduce an erroneous setting of the opening/closing state of each of the valves.

The present embodiments are described based on a setting method of supplying a predetermined gas from the gas source 247 to the process furnace 202. However, the number of gases used for processing the wafer 200 in the process furnace 202 is not limited to one. For example, a plurality of process gases may be used in accordance with a type of a film to be formed on the wafer 200. For example, when forming a silicon nitride film (SiN film), at least a silicon-containing gas and a nitrogen-containing gas are used, and when forming a silicon oxycarbonitride film (SiOCN film), a silicon-containing gas, a nitrogen-containing, an oxygen-containing gas and a carbon-containing gas are used. Therefore, in a case where two types of gases, that is, a process gas “A” and a process gas “B”, are used when processing the wafer 200, the setting of the opening/closing states of the valves within a range from a gas source “A” of the process gas “A” to the process furnace 202 and the setting of the opening/closing states of the valves within a range from a gas source “B” of the process gas “B” to the process furnace 202 are performed.

Further, in the case where the process gas “A” and the process gas “B” are used when processing the wafer 200, when a processing of the wafer 200 is performed by performing at least a process gas “A” supply step (which is a source gas supply step), a first purge gas supply step (which is a purge step), a process gas “B” supply step (which is a reactive gas supply step) and a second purge gas supply step (which is a purge step), the setting of the opening/closing states of the valves are performed among the gas source “A”, the gas source “B”, a purge gas source and the process furnace 202. It is needless to say that the gas pipes between the transfer chamber 124 and a gas source (for example, the purge gas source), which are not directly related to the processing of the wafer 200, can be similarly colored as long as the gas pipes described above are displayed on the gas pattern screen.

Further, as shown in FIG. 16, a parameter registration step is performed after the registration button 270 is operated. When the parameter registration step is performed, parameter information set by using the recipe edit screen and including the setting of the opening/closing states of the valves can be written to the recipe being created. Then in a subsequent parameter save processing step, the recipe is saved (or stored) in the memory 240c. In the parameter save processing step, since the recipe can be saved after the recipe is completed, a save confirmation screen (not shown) may be displayed to confirm whether or not to save the recipe. Further, it is possible that the registration button 270 provided at other appropriate location on the recipe edit screen instead of being provided on the gas pattern screen.

Further, on the recipe edit screen, not only the gas pattern screen but also a region for setting the parameters such as the temperature, the pressure and the parameters for the transfer structure (which are not shown) is displayed on the same screen. It is possible to set the parameters described above on the recipe edit screen, and when an operation (or an instruction) of the parameters is accepted, a process parameter selection step or a transfer parameter selection step shown in FIG. 16 is performed by the controller 240. Then, in accordance with the operation (or the instruction) of the parameters, one of the parameters such as the temperature, the pressure and the parameters for the transfer structure is selected, and subsequently, an edit such as an input, a change and a correction regarding the selected parameter is accepted.

Then, once the setting of the parameters including the opening/closing state of the valve on the recipe edit screen is completed, a first temporary save process (that is, a process of writing at least the parameter information on the recipe edit screen to the recipe) is performed by pressing the registration button 270. Subsequently, by using a step selection structure such as a step selection button displayed on the recipe edit screen, the controller 240 accepts (or receives) a selection of a step for a switching destination. When the screen switching button 280 is pressed, the step selected by the step selection structure is displayed. Further, it is possible to set the parameters including the opening/closing state of the valve by using the recipe edit screen. Further, according to the present embodiments, a step selection step by using the step selection structure may be omitted, and the controller 240 is configured to switch and display the recipe edit screen for a subsequent step even when the screen switching button 280 is pressed.

Further, a recipe selection structure for selecting another recipe may be provided on the recipe edit screen, and it is possible to copy a recipe selected by the recipe selection structure. However, even when a type of the film is the same, it cannot be said that the gas pattern screen will be exactly the same. Therefore, even when a recipe copy function is used, it is preferable to set the opening/closing states of the valve by using the gas pattern screen. As a result, a parameter editing operation for each step is reduced, thereby making it possible to shorten a recipe creation time.

Further, the controller 240 is configured to terminate a process flow shown in FIG. 16 when a process of exiting from the recipe edit screen to another screen such as another main screen is performed. For example, before switching to another screen, a confirmation screen for confirming whether to really terminate a work (or an operation) on the recipe edit screen may be displayed.

According to the embodiments of the present disclosure, it is possible to obtain one or more among the following effects (a) through (f).

(a) According to the embodiments of the present disclosure, the gas pipe is colored in the gas color with the dashed line when at least one of the valves connected thereto is in the open state, even though not the entirety of the valves between the gas source and the gas pipe are in the open state. Therefore, on the gas pattern screen, it is possible to see which gas pipe will be affected when an arbitrary valve is switched to the open state.

(b) Further, according to the embodiments of the present disclosure, it is possible to trace a piping route from two directions, that is, from a direction of the gas source and from a direction of the target gas supply destination to which the gas is supplied. Thereby, it is possible to easily grasp which valve should be switched to the open state in order to realize the piping route capable of satisfying specified conditions as compared with a case where the piping route can be traced from the direction of the gas source alone.

(c) Further, according to the embodiments of the present disclosure, by selecting the icon displayed on the gas pattern screen and displaying the operation screen, it is possible to set the parameters of various components such as the flow rate controllers, the vaporizer, the exhaust apparatus and the pressure regulator.

(d) Further, according to the embodiments of the present disclosure, it is possible to register various parameters set as described above after the piping route from the gas source to the target gas supply destination is fully determined. Thereby, it is possible to prevent the user from erroneously setting the piping route.

(e) Further, according to the embodiments of the present disclosure, in addition to various parameters such as the opening/closing state of the valve set by using the gas pattern screen, it is possible to set the parameter in a state where the region for setting the parameters such as the temperature and the pressure is displayed on the same screen. Thereby, it is possible to prevent the user from erroneously setting the piping route.

(f) Further, according to the embodiments of the present disclosure, in addition to reducing erroneous settings of various parameters such as the opening/closing state of the valve set by using the gas pattern screen, it is possible to set the parameters such as the temperature and the pressure by copying the recipe. Thereby, it is possible to prevent the user from erroneously setting the parameters, and it is also possible to shorten the recipe creation time.

### Other Embodiments of Present Disclosure

While the technique of the present disclosure is described in detail by way of the embodiments described above, the technique of the present disclosure is not limited thereto. The technique of the present disclosure may be modified or combined with one another in various ways without departing from the scope thereof.

For example, the substrate processing apparatus 10 according to the embodiments of the present disclosure can be applied to not only a semiconductor manufacturing apparatus capable of manufacturing a semiconductor device but also to an apparatus capable of processing a glass substrate such as an LCD apparatus. Further, the embodiments of the present disclosure can also be applied to an apparatus such as an exposure apparatus, a lithography apparatus, a coating apparatus and a processing apparatus using plasma.

According to some embodiments of the present disclosure, it is possible to set the opening/closing state of the valve by using the operation screen such that the desired state of the gas flow can be implemented while checking which gas pipe is affected when an arbitrary valve is opened on the operation screen.

1. A method of manufacturing a semiconductor device, comprising
(A) creating a recipe by setting opening/closing states of a plurality of valves on a gas pattern screen; and
(B) processing a substrate by performing the recipe created in (A),
wherein (A) comprises:
(a) selecting a gas pipe on the gas pattern screen when an opening/closing state of any valve among the plurality of valves changes on the gas pattern screen; and
(b) confirming opening/closing states of one or more valves connected to the gas pipe selected in (a).

2. The method of claim 1, wherein (A) further comprises
(c) confirming whether or not at least one among one or more valves between a gas source and the gas pipe selected in (a) is in an open state when it is confirmed in (b) that at least one among the one or more valves connected to the gas pipe selected in (a) is in the open state.

3. The method of claim 1, wherein (A) further comprises
(d) coloring the gas pipe selected in (a) in a gas color with a dashed line when it is confirmed in (b) that the at least one among the one or more valves connected to the gas pipe selected in (a) is in an open state.

4. The method of claim 1, wherein (A) further comprises
(e) performing a coloring process for a subsequent gas pipe after terminating a coloring process for the gas pipe selected in (a) when it is confirmed in (b) that an entirety of the one or more valves connected to the gas pipe selected in (a) are in a closed state.

5. The method of claim 2, wherein (A) further comprises
(f) switching a coloring state of the gas pipe selected in (a) from a dashed line in a gas color to a solid line in the gas color when it is confirmed in (c) that an entirety of the one of one or more valves between the gas source and the gas pipe selected in (a) are in the open state.

6. The method of claim 1, wherein the gas pattern screen is configured such that the opening/closing states of any valves among the plurality of valves are capable of being changed in (a).

7. The method of claim 1, wherein the gas pattern screen is configured to at least display one or more valves located within a range from a supplier capable of supplying a source material into a reaction chamber to an exhauster capable of exhausting an inner atmosphere of the reaction chamber such that an inner pressure of the reaction chamber reaches and is maintained at a vacuum level.

8. The method of claim 7, wherein the gas pattern screen is further configured to display one or more icons respectively indicating one or more selected from the group consisting of a flow rate controller, a vaporizer, an exhaust apparatus and a pressure regulator.

9. The method of claim 8, wherein the one or more icons respectively indicating the one or more selected from the group consisting of the flow rate controller, the vaporizer, the exhaust apparatus and the pressure regulator are displayed on the gas pattern screen such that parameters related to one or more selected from the group consisting of the flow rate controller, the vaporizer, the exhaust apparatus and the pressure regulator are capable of being set.

10. The method of claim 1, wherein an operation screen containing the gas pattern screen is displayed in (A), and the operation screen is configured such that parameters related to one or more selected from the group consisting of a temperature, a pressure and parameters of a transfer structure are capable of being set.

11. The method of claim 10, wherein the operation screen further comprises a registration interface configured to register the parameters set by using the operation screen, and
wherein the registration interface is further configured to accept contents of the parameters set by using the operation screen when the registration interface is pressed.

12. The method of claim 10, wherein the operation screen further comprises a registration interface configured to register the parameters set by using the operation screen, and
wherein the registration interface is configured to be capable of being pressed when an entirety of one or more valves located within a range from a gas source to a target gas supply destination on the gas pattern screen are in an open state.

13. The method of claim 12, wherein the registration interface is further configured to be incapable of being pressed when the entirety of the one or more valves between the gas source to the target gas supply destination on the gas pattern screen are not in the open state.

14. The method of claim 13, wherein the recipe comprises a plurality of steps, and
wherein the operation screen comprises a screen switching interface capable of being pressed after contents of the parameters set by using the operation screen is accepted by the registration interface and capable of switching a screen from that for a step among the plurality of steps to that for another step among the plurality of steps.

15. A non-transitory computer-readable recording medium storing a program that causes by a computer to perform:
(A) creating a recipe by setting opening/closing states of a plurality of valves on a gas pattern screen; and
(B) processing a substrate by executing the recipe created in (A),
wherein (A) comprises:
(a) selecting a gas pipe on the gas pattern screen when an opening/closing state of any valve among the plurality of valves changes on the gas pattern screen; and
(b) confirming opening/closing states of one or more valves connected to the gas pipe selected in (a).

16. A substrate processing apparatus comprising
a controller configured to be capable of performing:
(A) creating a recipe by setting opening/closing states of a plurality of valves on a gas pattern screen; and
(B) processing a substrate by executing the recipe created in (A),
wherein (A) comprises:
(a) selecting a gas pipe on the gas pattern screen when an opening/closing state of any valve among the plurality of valves changes on the gas pattern screen; and
(b) confirming opening/closing states of one or more valves connected to the gas pipe selected in (a).
